(19) United States
(12) Patent Application Publication
(10) Pub. No.: US 2003/0112053 A1
(43) Pub. Date: Jun. 19, 2003

(54) Semiconductor circuit technology

(76) Inventors: Rolf Reber, Ulm (DE); Michael Ludwig, MC Leiden (NL)

Correspondence Address: CROWELL & MORING LLP, INTELLECTUAL PROPERTY GROUP, P.O. BOX 14300, WASHINGTON, DC, 20044-4300, US

(21) Appl. No.: 10/289,444

(22) Filed: Nov. 7, 2002

(30) Foreign Application Priority Data
Nov. 8, 2001 (DE) 101 54 996.2

(51) Int. Cl. H03K 17/60

(52) U.S. Cl. 327/482

(57) ABSTRACT

A semiconductor circuit for switching and/or amplitude influencing of an analog desired signal fed to the input (EA, AE) of the circuit (1) to an analog actual signal in the high-frequency range generated by the circuit at the output (AE, EA). The circuit (1) has two bipolar transistors (T1, T2) arranged with respect to one another such that the collector terminal (K1, K2) of the one bipolar transistor (T1, T2) is connected with the emitter terminal (E2, E1) of the other bipolar transistor (T2, T1) and vice-versa. The bipolar transistors (T1, T2) are controlled by a control quantity fed to the base terminals (B1, B2) of the transistors (T1, T2).

### BACKGROUND AND SUMMARY OF THE INVENTION

This application claims the priority of U.S. Pat. No. 101 54 996.2 filed Nov. 8, 2001, the disclosure of which is expressly incorporated by reference herein.

The invention relates to a circuit in semiconductor switching technology.

From high-frequency engineering, analog semiconductor circuits are known in which field effect transistors (FET) and diodes (PIN diodes) are used for the switching of analog signals. A disadvantage of these circuits is the cost-intensive production of FET transistors by MOSFET, HEMT or MESFET processes as well as the high space requirement of the circuit.

It is an object of the invention to provide a circuit in semiconductor technology circuit for switching of analog signals which eliminate prior art disadvantages.

According to the invention, two bipolar transistors are present in the semiconductor circuit for the switching and/or for influencing the amplitude of an analog desired signal fed to the input of the circuit to an analog actual signal in the high-frequency range generated by the circuit at the output, which transistors are arranged with respect to one another such that the collector terminal of the one bipolar transistor is connected with the emitter terminal of the other bipolar transistor and vice-versa. As a result, the bipolar transistors can be controlled by way of their base terminal using a control quantity.

The circuit according to the invention can advantageously be produced by means of bipolar semiconductor processes, particularly by means of SiGe or GaAs semiconductor technology. It is therefore becomes possible that, in addition to the known implementation of amplifiers and fast digital circuits in bipolar semiconductor technology, circuits with amplitude control elements and phase control elements can now be produced for analog signal processing in bipolar semiconductor technology. This permits a much lower-cost production. In addition, the circuits, which, in particular, are MMICs (monolithic microwave integrated circuits) can be implemented in a more space-saving manner on a single microchip. Another advantage is the simpler control of the MMICs produced in bipolar semiconductor technology.

The circuit according to the invention can be used particularly in T/R (transmit/receive) modules of active phased array radar antennas.

In an advantageous embodiment of the circuit according to the invention, the bipolar transistors are controlled by means of an analog or digital control quantity. In this case, the control quantity may either be a current signal or a voltage signal. According to the invention, the control takes place by way of the base terminal of the transistors. When the bipolar transistors are controlled by means of a digital control quantity, it is possible to switch the circuit according to the invention in each case between an on- and an off-condition. In the on-condition, the path between the input and the output is switched to be conductive, and in the off-condition, it is switched to be non-conductive.

When an analog control quantity provides the control, it is possible to continuously change the amplitude of the signal to be controlled because, corresponding to the control quantity, the path between the input and the output of the circuit according to the invention is switched continuously between conductive and non-conductive.

In the circuit according to the invention, one network is advantageously connected in front of the base terminal of each of the respective bipolar transistors. By means of the networks, an uncoupling as well as an adjustment of the working point of the bipolar transistors is permitted.

In another advantageous embodiment of the invention, a joint network for the uncoupling as well as the adjustment of the working point of the bipolar transistors is connected in front of the base terminals of the two bipolar transistors.

In this case, a network may advantageously be a resistor or a logic circuit, particularly a temperature compensation circuit, a linearization circuit or a voltage converter. When a resistor is used, a control current is generated, for example, from a control voltage.

The networks can also be implemented in bipolar semiconductor technology.

Other objects, advantages and novel features of the present invention will become apparent from the following detailed description of the invention when considered in conjunction with the accompanying drawings.

### BRIEF DESCRIPTION OF THE DRAWINGS

The invention will be explained in detail by means of the figures.

FIG. 1 is a view of a first advantageous embodiment of the circuit according to the invention with two separate networks for the base terminals;

FIG. 2 is a view of a second advantageous embodiment of the circuit according to the invention with a joint network for the base terminals.

### DETAILED DESCRIPTION OF THE PREFERRED EMBODIMENTS

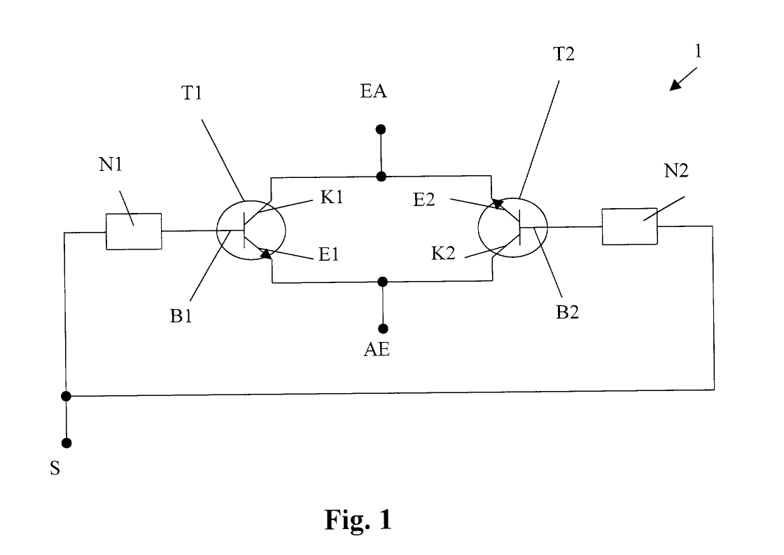

FIG. 1 shows a first advantageous embodiment of the circuit according to the invention. The two bipolar transistors T1 and T2 are arranged anti-parallel with respect to one another, the collector K1 of the one transistor T1 being connected with the emitter E2 of the other transistor T2. Correspondingly, the emitter E1 of one transistor T1 is then connected with the collector K2 of the other transistor T2. In this case, the two transistors T1, T2 can either be constructed as npn-transistors or as pnp-transistors.

The connection paths between the two transistors T1 and T2 each have a terminal EA, AE. The desired signal is fed to the circuit 1 according to the invention at the terminal EA. At terminal AE, the actual signal is taken from the circuit 1 according to the invention. Naturally, it is also possible that the desired signal is fed to terminal AE and the actual signal is obtained from terminal EA.

The networks N1, N2 are connected by way of two connection lines in the connection point S. In addition, each network N1, N2 is connected with a base terminal B1, B2 of the corresponding transistor T1, t2.

The control signal is finally fed by the connection point S.

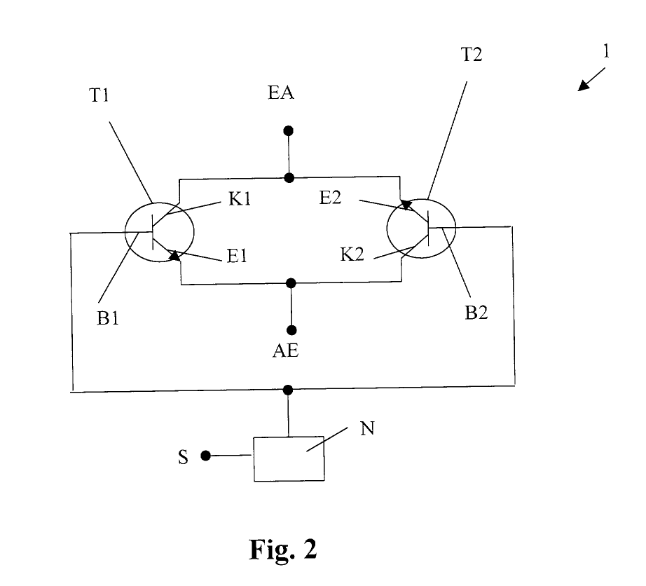

FIG. 2 shows a second advantageous embodiment of the circuit according to the invention. The wiring of the transistors T1, T2 corresponds essentially to the wiring described in FIG. 1. In contrast, in FIG. 2, the base terminals B1, B2 of the transistors T1, T2 are connected with a joint network N to which the control signal is fed by way of the connection point S.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1. A semiconductor circuit for at least one of switching and amplitude influencing of an input analog desired signal to provide an output analog actual signal in a high-frequency range, said circuit comprising:
a first and a second bipolar transistor wherein a collector terminal of said first bipolar transistor is connected with an emitter terminal of said second bipolar transistor and wherein a collector terminal of said second bipolar transistor is connected with an emitter terminal of said first bipolar transistor;
at least one control input with one of said at least one control inputs being connected respectively to a base terminal of said first and second bipolar transistors to control said first and second transistors.

2. The circuit according to claim 1, wherein said control input is one of an analog and a digital signal.

3. The circuit according to claim 1, further including at least one network for adjusting a working point of each of said bipolar transistors wherein said at least one network is connected between said control input and said base terminal of each of said bipolar transistors.

4. The circuit according to claim 1, further including a joint network for adjusting a working point of each of said bipolar transistors wherein said joint network is connected between said control input and said base terminals of each of said bipolar transistor.

5. The circuit according to claim 3, wherein said network is one of a resistor circuit and a logic circuit.

6. The circuit according to claim 4, wherein said joint network is one of a resistor circuit and a logic circuit.

7. The production of a circuit according to claim 1, by means of a bipolar semiconductor process.

8. The production according to claim 7, wherein said bipolar semiconductor process is SiGe semiconductor technology.

9. The production according to claim 7, wherein said bipolar semiconductor process is GaAs semiconductor technology.

10. A semiconductor switching circuit comprising:
a first and second bipolar transistor connected in an anti-parallel arrangement and receiving a first signal and outputting a second high frequency range signal;
control means responsive to an input control signal to one of control switching between the input and output by a conductive and non-conductive operation of the circuit and contact the amplitude of the input signal in a continuous manner by continuous switching between a conductive and non-conductive operation of the circuit.

11. The circuit according to claim 10, wherein the control means provides a digital control signal.

12. The circuit according to claim 10, wherein said control means provides an analog control signal.

13. A circuit according to claim 10, wherein said control means is one of a resistor circuit and a logic circuit.

14. A circuit according to claim 10, wherein said one of a resistor circuit and a logic circuit includes one of a temperature compensation circuit, a linearization circuit and a voltage converter.

15. A circuit according to claim 5, wherein said one of a resistor circuit and a logic circuit includes one of a temperature compensation circuit, a linearization circuit and a voltage converter.

16. A circuit according to claim 6, wherein said one of a resistor circuit and a logic circuit includes one of a temperature compensation circuit, a linearization circuit and a voltage converter.
